(19) United States
(12) Patent Application Publication
(10) Pub. No.: US 2025/0081850 A1
(43) Pub. Date: Mar. 6, 2025

(54) SYSTEM AND METHODS FOR HIGH TEMPERATURE LIQUID-METAL THERMOELECTRIC POWER CONVERSION

(71) Applicant: Atomos Nuclear and Space Corporation, Denver, CO (US)

(72) Inventor: Lucas Brady Beveridge, Denver, CO (US)

(73) Assignee: Atomos Nuclear and Space Corporation, Denver, CO (US)

(21) Appl. No.: 18/435,466

(22) Filed: Feb. 7, 2024

Related U.S. Application Data
(60) Provisional application No. 63/443,813, filed on Feb. 7, 2023.

(51) Int. Cl. H10N 10/81; H10N 10/17

(52) U.S. Cl. CPC H10N 10/81; H10N 10/17

(57) ABSTRACT

A thermoelectric generator system includes a junction formed from at least one of a metal, an alloy, and a composite that is allowed to at least partially melt during system operation. The thermoelectric generator system may be configured to operate high temperatures greater than 1200 K. The thermoelectric generator system includes a liquid metal TEG junction including a first leg with a low Seebeck coefficient and a second leg with a high Seebeck coefficient. Each one of the first and second legs includes an electrically and thermally insulating reservoir for containing a liquid metal therein and an electrode for providing electrical and thermal conduction out of the liquid metal. The reservoir may include one or more features for disrupting convective flow to minimize unwanted heat transport.

### REFERENCE TO RELATED APPLICATIONS

The present application claims the benefit of U.S. Pat. App. No. 63/443,813, filed 2023 Feb. 7 and titled “System and Methods for High Temperature Liquid-Metal Thermoelectric Power Conversion,” which is incorporated hereby in its entirety by reference.

### FIELD OF THE INVENTION

The present invention relates to power conversion. In particular, but not by way of limitation, the present invention relates to high temperature power conversion systems and methods suitable for aerospace applications.

### DESCRIPTION OF RELATED ART

High temperature power conversion is essential for spacecraft with high power requirements in order to minimize the mass of radiators for rejecting waste heat. In some cases, a power conversion system with a high rejection temperature may be more advantageous than a high conversion efficiency in minimizing the overall system mass.

Thermoelectric energy conversion has a long history, especially in radioisotope power sources. However, existing systems are typically semiconductor-based devices, which are temperature limited due to the relatively low melting point of semiconductor junctions. Further, semiconductor devices are susceptible to ionizing radiation, which can be a drawback in some nuclear systems.

Thus, there is a need for an improved power conversion systems suitable for a variety of spacecraft applications.

### BRIEF DESCRIPTION OF DRAWINGS

FIG. 1 illustrates a liquid metal thermoelectric generator (TEG) junction, in accordance with an embodiment.

FIG. 2 shows a comparison of commercial and liquid-metal TEG for use with spacecraft as summarized in Table 1.

For simplicity and clarity of illustration, the drawing figures illustrate the general manner of construction, and descriptions and details of well-known features and techniques may be omitted to avoid unnecessarily obscuring the embodiments detailed herein. Additionally, elements in the drawing figures are not necessarily drawn to scale. For example, the dimensions of some of the elements in the figures may be exaggerated relative to other elements to help improve understanding of the described embodiments. The same reference numerals in different figures denote the same elements.

The word “exemplary” is used herein to mean “serving as an example, instance, or illustration.” Any embodiment described herein as “exemplary” is not necessarily to be construed as preferred or advantageous over other embodiments. In the following detailed description, references are made to the accompanying drawings that form a part hereof, and in which are shown by way of illustrations or specific examples. These aspects may be combined, other aspects may be utilized, and structural changes may be made without departing from the present disclosure. Example aspects may be practiced as methods, systems, or apparatuses. The following detailed description is therefore not to be taken in a limiting sense, and the scope of the present disclosure is defined by the appended claims and their equivalents.

### SUMMARY OF THE INVENTION

The following presents a simplified summary relating to one or more aspects and/or embodiments disclosed herein. As such, the following summary should not be considered an extensive overview relating to all contemplated aspects and/or embodiments, nor should the following summary be regarded to identify key or critical elements relating to all contemplated aspects and/or embodiments or to delineate the scope associated with any particular aspect and/or embodiment. Accordingly, the following summary has the sole purpose to present certain concepts relating to one or more aspects and/or embodiments relating to the mechanisms disclosed herein in a simplified form to precede the detailed description presented below.

In an embodiment, a thermoelectric generator system includes a junction formed from at least one of a metal, an alloy, and a composite that is allowed to at least partially melt during system operation. In certain embodiments, the thermoelectric generator system is configured to operate high temperatures greater than 1200 K.

In an embodiment, the thermoelectric generator system includes a liquid metal TEG junction including a first leg with a low Seebeck coefficient and a second leg with a high Seebeck coefficient. Each one of the first and second legs includes an electrically and thermally insulating reservoir for containing a liquid metal therein and an electrode for providing electrical and thermal conduction out of the liquid metal. In certain embodiments, the reservoir may include one or more features for disrupting convective flow to minimize unwanted heat transport. In certain embodiments, liquid metal TEG junction includes a hot side and a cold side, and, an average temperature of the hot side and the cold side is greater than 1200 K. In other embodiments, both the hot side and the cold side of the TEG system operates at temperatures greater than 1200 K. In embodiments, at least one of the first and second legs operate at sufficiently high temperatures such that the liquid metal contained therein are molten. In certain embodiments, the cold side may be at or near room temperature (e.g., ˜293 K).

These and other features, and characteristics of the present technology, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention. As used in the specification and in the claims, the singular form of ‘a’, ‘an’, and ‘the’ include plural referents unless the context clearly dictates otherwise.

### DETAILED DESCRIPTION OF THE INVENTION

Due to their simplicity and reliability, solid state power conversion such as thermoelectric generators (TEGs) have practical and economic benefits over more complex mechanical conversion such as Brayton or Stirling cycles.

Some metals have sufficient Seebeck coefficients to produce a reasonable conversion efficiency comparable to semiconductor devices, but only at temperatures (and temperature differences) where one or both of the metal legs in the junction are molten. For example, using liquid antimony and bismuth as legs in a junction would produce a conversion efficiency of 5.8% with the hot side at 1750K, and a temperature difference of 850 K, and maximum current of 22.9 Amperes per junction. Such performance amounts to a power of 2.29 W per junction. Fabricating densely packed junctions may produce up to 10 W/cm2, which power output is comparable to thermionic conversion [3] which is notable for high power density.

### Liquid-Metal TEG Concept

The conversion efficiency of any thermoelectric device depends on the “Figure of Merit,” which is a parameter that depends on electrical and thermal conductivity, Seebeck coefficient, and the average of hot and cold side temperatures. The temperature difference determines the potential across the junction. Conventional TEGs use semiconductors to increase the difference in Seebeck coefficients, and thus conversion efficiency. Modern commercial TEGs can achieve up to 12% efficiency [4], but cannot operate at high temperatures (i.e., >1000° C.) due to the temperature sensitivities of the semiconductor junctions, on which commercial TEGs are built. However, with metals such as bismuth and antimony in the legs (although there are numerous possible combinations of other materials), the difference in Seebeck coefficient is enough to reach a conversion efficiency of around 6% at high temperature (hot side ˜1700 K, cold side ˜900 K).

This concept is similar to traditional TEG devices, replacing one or both of the legs in a junction made from a metal, alloy, or composite that is allowed to melt fully or partially when in operation, or at ambient conditions. The use of liquid metals allows the device to operate at much higher temperatures, so long as the highest temperature never exceeds the boiling point for either of the legs.

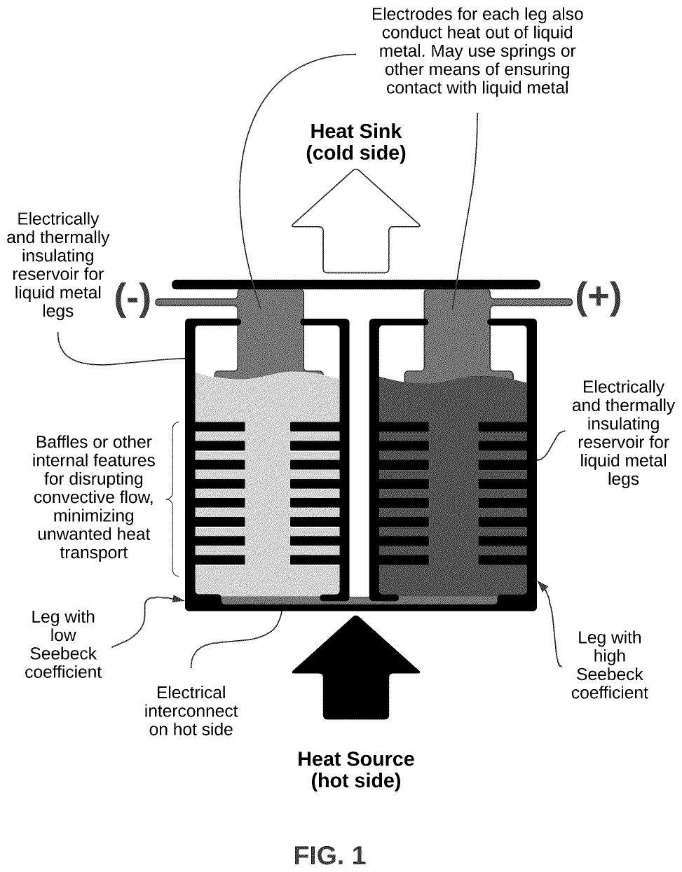

FIG. 1 illustrates a single liquid metal thermoelectric generator (TEG) junction, in accordance with an embodiment. Just as in a conventional TEG, one leg has a far larger Seebeck coefficient (or thermoelectric power) than the other. This characteristic produces a potential difference that can be used to drive a current in a circuit.

While there are some similarities to a conventional TEG, there are a few key differences between the conventional TEG and the system illustrated in FIG. 1. For instance, the thermoelectric materials in the leg with the liquid metal must be contained in a thermally and electrically insulating reservoir. It is possible to not use a reservoir, if one of the legs is based on a solid material. For example, the system of FIG. 1 may have one leg that is a high temperature semiconductor or other solid material, in which case only one leg will need a reservoir. As the TEG system shown in FIG. 1 does not require the use of semiconductors in the junction, the system is highly tolerant to ionizing radiation, which would make the system useful in harsh environments where conventional, semiconductor-based TEGs would fail.

In certain embodiments, the reservoirs for containing the liquid metal may require baffles or other internal geometry to prevent convection from carrying heat to the cold side without generating current.

The key requirement for this device is the use of metals, alloys, or other materials that may be liquid at very high temperatures (much higher than conventional TEGs), while having sufficiently high or low Seebeck coefficients (depending on which side of the junction the material is being used) to reach a practical conversion efficiency. As described above, the reservoir for containing the liquid metal should be both thermally and electrically insulating while also being able to tolerate high temperatures. The plates on either ends of the junctions for seal the reservoir(s) should also be thermally and electrically insulating and tolerant of high temperatures, while being able to conduct heat to and from the junctions.

The use of composite materials as the junction material may also improve performance of the liquid metal TEG. For example, one leg might be a mix of a solid that conducts electricity relatively well (such as tungsten), combined with a material with a very large Seebeck coefficient that may not conduct electricity well by itself (such as molten selenium metal). The combination of these materials may produce a very high potential across the legs of a cell and a result in a high conversion efficiency. Other composites and alloys, which may provide desirable qualities in one or both of the junction legs of such a device, are contemplated, and are considered to be a part of the present disclosure.

### Applications and Performance Comparisons

One possible application of the liquid metal TEG system is power conversion on spacecraft, where minimizing system mass is of great importance. Commercial TEGs can reach up 12% efficiency, but only if the cold-side is near room-temperature. Such a low rejection temperature requires the surface area of the radiators to be larger than practicable for spacecraft applications due to the Stefan-Boltzmann law.

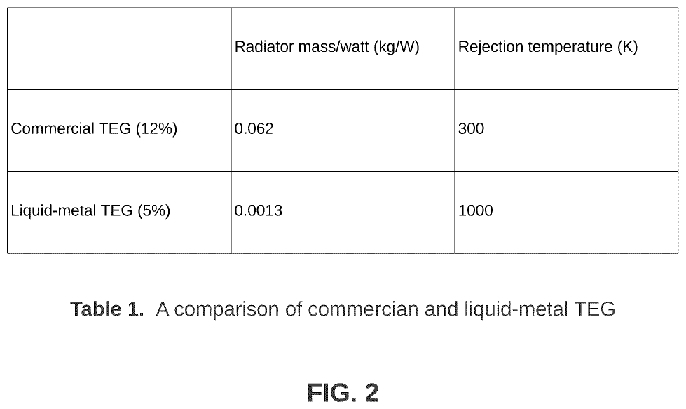

A comparison of commercial and liquid-metal TEG for use with spacecraft is shown in Table 1. of FIG. 2. Table 1 compares radiator specific masses, assuming an areal density of 7 kg/m2. The resulting calculations show the liquid metal TEG has a conversion efficiency of 5%, and the commercial TEG is 12%. However, the liquid metal TEG provides only ˜ 1/50 of the mass of the commercial TEG due to its high rejection temperature, thus providing significant advantages for spacecraft applications despite performing with less than half the efficiency of the commercial TEG.

Due to the high operating temperature, liquid-metal TEGs may also be well suited for some terrestrial uses, such as waste-heat recovery in industrial facilities. In such an application, it would be possible to maintain a much lower rejection temperature, since mass is not a concern in this application. Consequently, the liquid-metal TEG may provide much greater efficiency, as high as 10% for the bismuth/antimony junction example described earlier.

Another application is in a compact nuclear power reactor, where the system is volumetrically limited, and ionizing radiation would quickly destroy a semiconductor cell in a commercial TEG. Just as with waste-heat recovery, the conversion efficiency of a liquid metal TEG would be much greater that of a commercial TEG, along with a lower rejection temperature and much longer operating life in this challenging application environment. As the liquid TEG does not include any moving parts requiring mechanical maintenance, plant design and safety analysis of the nuclear power reactor may be greatly simplified as well.

While existing thermoelectric devices based on liquid metals do exist, they do not operate in the same way as the presently described liquid metal TEG. For example, one existing concept requires circulation of a molten metal and vapor in a loop through porous electrodes [5], and another merely uses liquid metal interconnects in a conventional TEG to make the device flexible [6]. In contrast, the liquid metal TEG as described herein provides advantages over previously described liquid metal thermal electric devices as well as conventional, semiconductor junction-based commercial TEGs, such that the described liquid metal TEG systems are suitable for extremely challenging and mass-constrained environments.

As used herein, the recitation of “at least one of A, B and C” is intended to mean “either A, B, C or any combination of A, B and C.” The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

The terms and expressions employed herein are used as terms and expressions of description and not of limitation, and there is no intention, in the use of such terms and expressions, of excluding any equivalents of the features shown and described or portions thereof. Each of the various elements disclosed herein may be achieved in a variety of manners. This disclosure should be understood to encompass each such variation, be it a variation of an embodiment of any apparatus embodiment, a method or process embodiment, or even merely a variation of any element of these. Particularly, it should be understood that the words for each element may be expressed by equivalent apparatus terms or method terms-even if only the function or result is the same. Such equivalent, broader, or even more generic terms should be considered to be encompassed in the description of each element or action. Such terms can be substituted where desired to make explicit the implicitly broad coverage to which this invention is entitled.

As but one example, it should be understood that all action may be expressed as a means for taking that action or as an element which causes that action. Similarly, each physical element disclosed should be understood to encompass a disclosure of the action which that physical element facilitates. Regarding this last aspect, by way of example only, the disclosure of a “protrusion” should be understood to encompass disclosure of the act of “protruding”-whether explicitly discussed or not—and, conversely, were there only disclosure of the act of “protruding”, such a disclosure should be understood to encompass disclosure of a “protrusion”. Such changes and alternative terms are to be understood to be explicitly included in the description.

### REFERENCES

[1] T. J. Seebeck, “Magnetische Polarisation der Metalle und Erze durch Temperatur-Differenz (Magnetic polarization of metals and minerals by temperature differences),” Abhandlungen der Königlichen Akademie der Wissenschaften zu Berlin (Treatises of the Royal Academy of Sciences in Berlin), pp. 265-373, 1825.
[2] T. J. Seebeck, “Ueber die Magnetische Polarisation der Metalle und Erze durch Temperatur-Differenz,” (On the magnetic polarization of metals and minerals by temperature differences),” Annalen der Physik und Chemie, vol. 6, no. 286, 1826.
[3] M. Campbell, T. Celenza, F. Schmitt, J. Schwede and I. Bargatin, “Progress Towards High Power Output in Thermionic Energy Converters,” Adv. Sci., vol. 8, no. 9, 5 May 2021.
[4] TECTEG MFR, “Pb/TAGS 400° C.-600° C. HIGH EFFICIENCY (up to 12%) TEG MODULES,” StableWP, 2019. [Online]. Available: https://web.archive.org/web/20230120185910/https://thermoelectric-generator.com/pbtags-400c-600c-high-efficiency-up-to-12-teg-modules/. [Accessed 20 Jan. 2023].
[5] J. B. Moreno, J. P. Abbin, C. E. Andraka and L. L. Lukens, “Liquid Metal Thermal Electric Converter Theoretical and Experimental Studies,” Sandia National Laboratory, Albuquerque, 1985.
[6] M. Zadan, M. H. Malakooti and C. Majidi, “Soft and Stretchable Thermoelectric Generators Enabled by Liquid Metal Elastomer Composites,” ACS Appl. Mater. Interfaces, vol. 12, no. 15, p. 17921-17928, 25 Mar. 2020.

1. A thermoelectric generator (TEG) system comprising a junction formed from at least one of a metal, an alloy, and a composite that is allowed to at least partially melt during system operation.

2. The thermoelectric generator system of claim 1, wherein the system is configured to operate at temperatures greater than 1200 K.

3. The thermoelectric generator system of claim 1,
wherein the junction includes a hot side and a cold side, and
wherein an average temperature of the hot side and the cold side is greater than 1200 K.

4. The thermoelectric generator system of claim 3,
wherein both the hot side and the cold side of the junction operates at temperatures greater than 1200 K.

5. The thermoelectric generator system of claim 3, wherein the hot side operates at sufficiently high temperatures such that the at least one of the metal, the allow, and the composite forming the junction becomes molten.

6. The thermoelectric generator of claim 3, wherein the cold side operates at or near room temperature.

7. The thermoelectric generator system of claim 1, wherein the junction includes a liquid metal TEG junction including a first leg with a first Seebeck coefficient and a second leg with a second Seebeck coefficient, the second Seebeck coefficient being higher than the first Seebeck coefficient.

8. The thermoelectric generator system of claim 3, wherein each one of the first and second legs includes an electrically and thermally insulating reservoir, for containing a liquid metal therein, and an electrode for providing electrical and thermal conduction out of the liquid metal.

9. The thermoelectric generator system of claim 4, wherein the reservoir includes at least one feature for disrupting convective flow.
